(19) United States
(12) Patent Application Publication
(10) Pub. No.: US 2009/0305453 A1
(43) Pub. Date: Dec. 10, 2009

(54) METHOD OF FABRICATING IMAGE SENSOR DEVICE

(75) Inventors: Cheng-Lin YANG, Hsinchu (TW); Chin-Poh PANG, Hsinchu (TW); Wu-Chieh LIU, Keelung (TW); Chi-Xiang TSENG, Hsinchu (TW)

Correspondence Address: Muncy, Geissler, Olds & Lowe, PLLC, P.O. BOX 1364, FAIRFAX, VA, 22038-1364, US

(73) Assignee: VisEra Technologies Company Limited

(21) Appl. No.: 12/136,433

(22) Filed: Jun. 10, 2008

(51) Int. Cl. H01L 21/00

(52) U.S. Cl. 438/70; 257/E21.001

(57) ABSTRACT

A method for fabricating an image sensor device is disclosed. A substrate having a sensing area comprising a pixel array therein is provided. A photoresist layer is coated over the substrate. Exposure is performed on at least two regions of the photoresist layer by at least two binary half-tone masks, respectively, in which a first and second binary half-tone masks of the two binary half-tone masks have different optical transparency distributions. Development is performed on the exposed photoresist layer to form a convex microlens array corresponding to the pixel array of the sensing area and comprising at least two microlenses with different convex profiles.

### BACKGROUND OF THE INVENTION

1. Field of the Invention

The invention relates to an image sensor device and more particularly to the profile control for a microlenses array in an image sensor device.

2. Description of the Related Art

As optoelectronic applications, such as digital cameras, digital video recorders, image capture capable mobile phones and monitors, become more and more popular, the demand for image sensor devices accordingly increase. An image sensor device is used for recording a change of a photo signal from an image and converting the photo signal into an electronic signal. After recording and processing the electronic signal, a digital image is generated. In general, image sensor devices can be categorized into two main types, one is charge coupled devices (CCD) and the other complementary metal oxide semiconductor (CMOS) devices.

The image sensor device typically comprises a pixel array. Each pixel includes a photosensor that produces a signal corresponding to the intensity of light impinging on the photosensor. When an image is focused on the array, signals can be employed to display a corresponding image. In conventional technology, a microlens array is correspondingly disposed above the pixel array and used for focusing light onto the pixel array. However, despite the use of the microlens array, a large amount of incident light is not directed efficiently onto the photosensors due to the geometry of the microlens array. The focal depth of the incident light to each photosensor is varied with the incident angle of the light (i.e. chief ray angle (CRA)). Accordingly, the microlens array with different focal depths reduces photosensitivity of the image sensor device.

Layered microlens structures for a microlens array have been proposed to address such a problem. However, poor ability to control the microlens profile, thus substantially having the same microlens shape, still reduces photosensitivity of the image sensor device.

Therefore, there is a need to develop novel microlens structures for a microlens array capable of increasing photosensitivity of the image sensor device.

### BRIEF SUMMARY OF THE INVENTION

A detailed description is given in the following embodiments with reference to the accompanying drawings. A method for fabricating an image sensor device is provided. An embodiment of a method for fabricating an image sensor device comprises providing a substrate having a sensing area comprising a pixel array therein. A photoresist layer is coated over the substrate. Exposure is performed on at least two regions of the photoresist layer by at least two binary half-tone masks, respectively, in which a first and second binary half-tone masks of the two binary half-tone masks have different optical transparency distributions. Development is performed on the exposed photoresist layer to form a convex microlens array corresponding to the pixel array of the sensing area and comprising at least two microlenses with different convex profiles.

### BRIEF DESCRIPTION OF DRAWINGS

The invention can be more fully understood by reading the subsequent detailed description and examples with references made to the accompanying drawings, wherein:

FIG. 1 is a plan view of an exemplary embodiment of an image sensor device with a microlens array according to the invention;

FIGS. 2A to 2B-1, 2B-2, and 2B-3 are cross sections of various exemplary embodiments of a method for fabricating an image sensor device shown in FIG. 1; and

FIGS. 3A to 3E are plan views of various exemplary embodiments of a mask projecting pattern for forming a microlens array according to the invention.

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims.

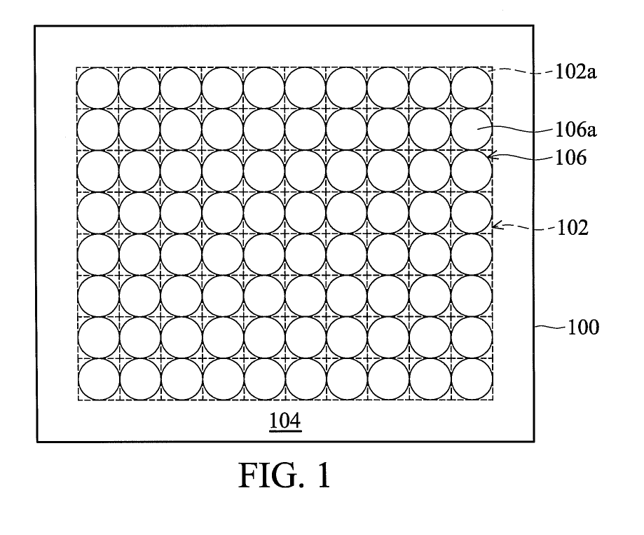

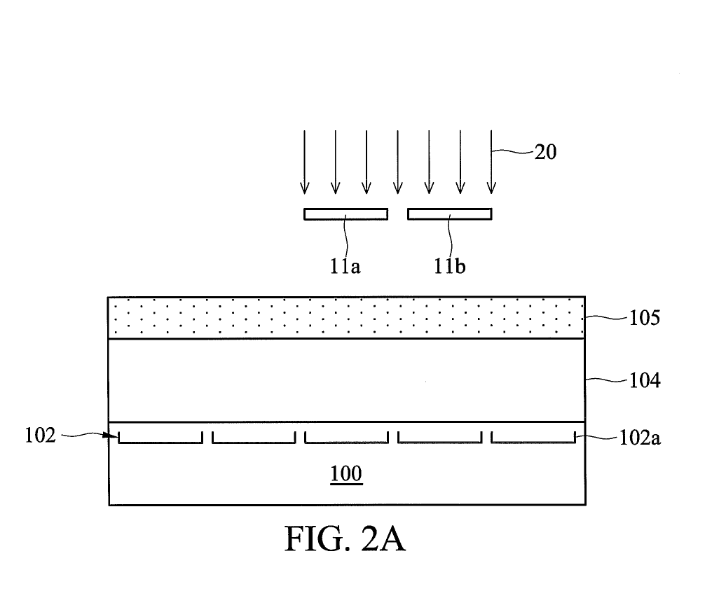

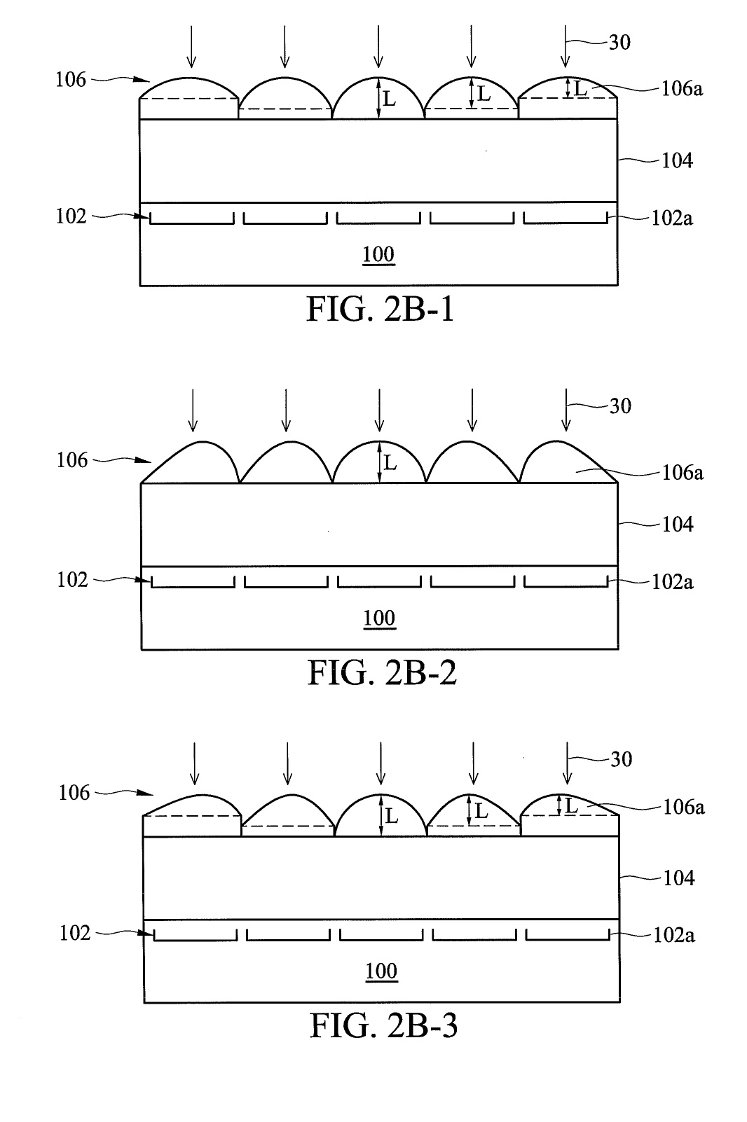

Referring to FIGS. 1 and 2B-1, an exemplary embodiment of an image sensor device with a microlens array according to the invention are shown in plan and cross sectional views, respectively. The image sensor device comprises a substrate 100, such as a semiconductor substrate, having a sensing area 102 comprising a pixel array therein. Each unit pixel in the pixel array of the sensing area 102 may include a photosensor 102a for converting a photo signal from an incident light (not shown) into an electronic signal.

An intervening layer 104 is disposed on the substrate 100. The intervening layer 104 may be composed of a multilayered structure comprising, for example, an interlayer dielectric (ILD) layer and an intermetal dielectric (IMD) layer for metallization. Moreover, the multilayered structure may further comprise a color filter array and an overlying passivation or planarization layer for protection thereof. In order to simplify the diagram, only a flat layer 104 is depicted.

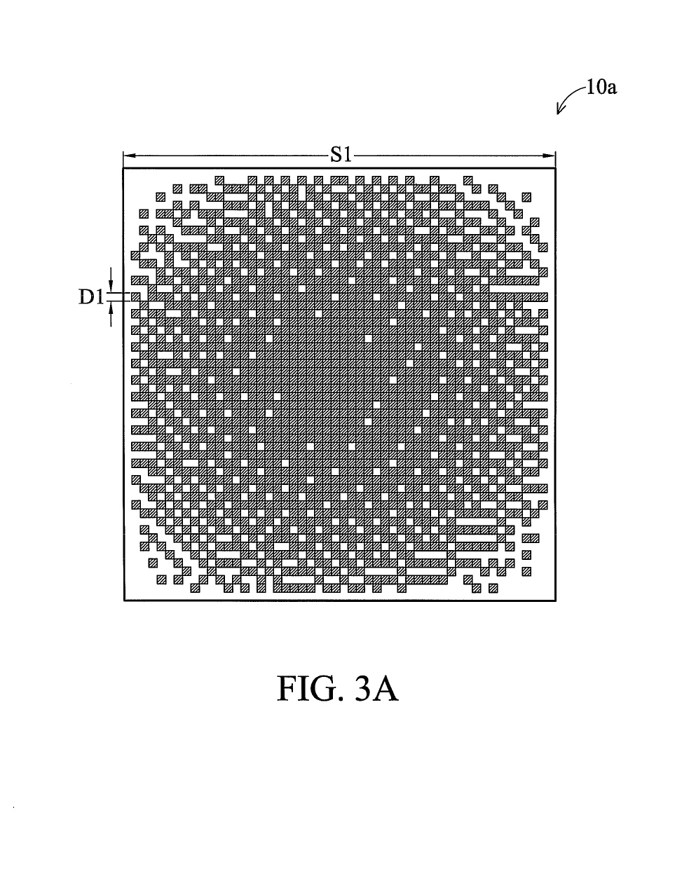

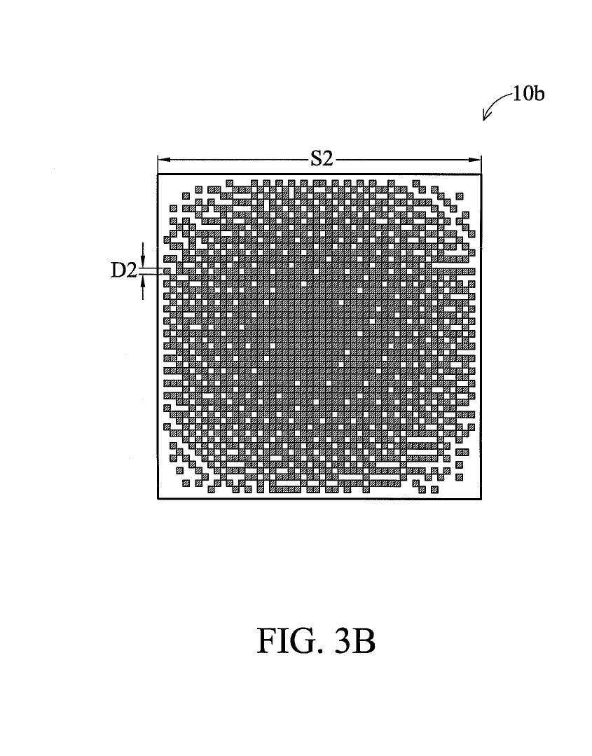

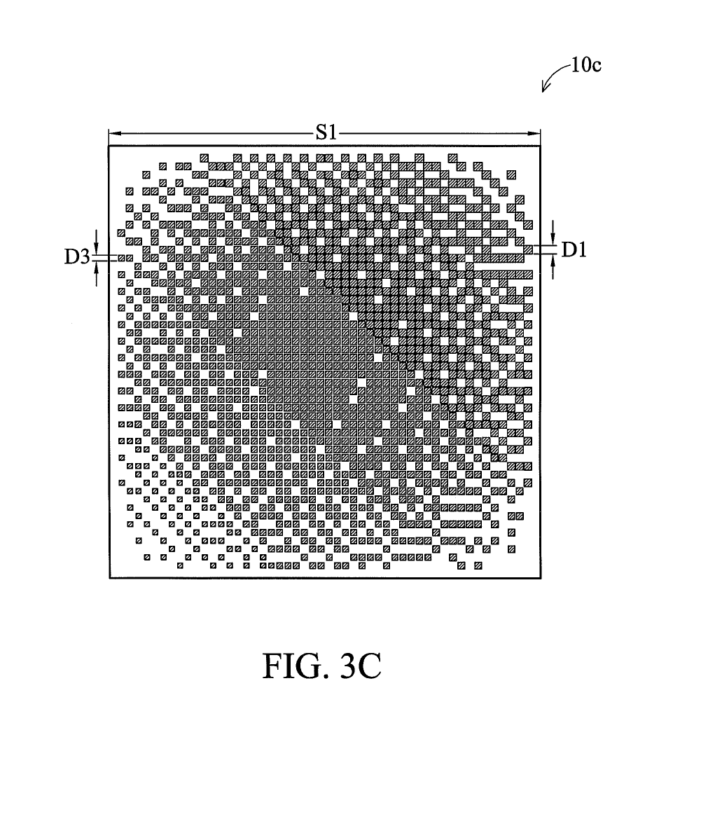

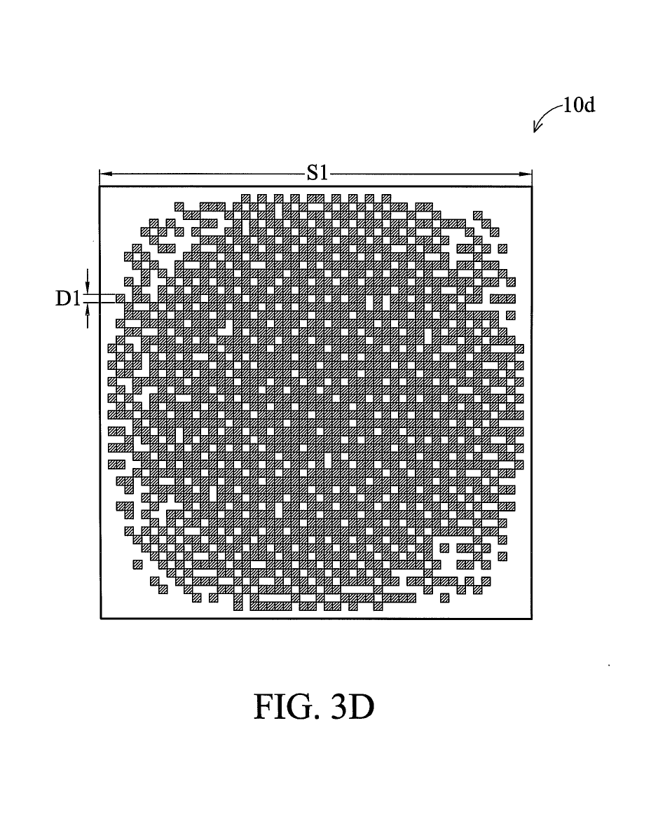

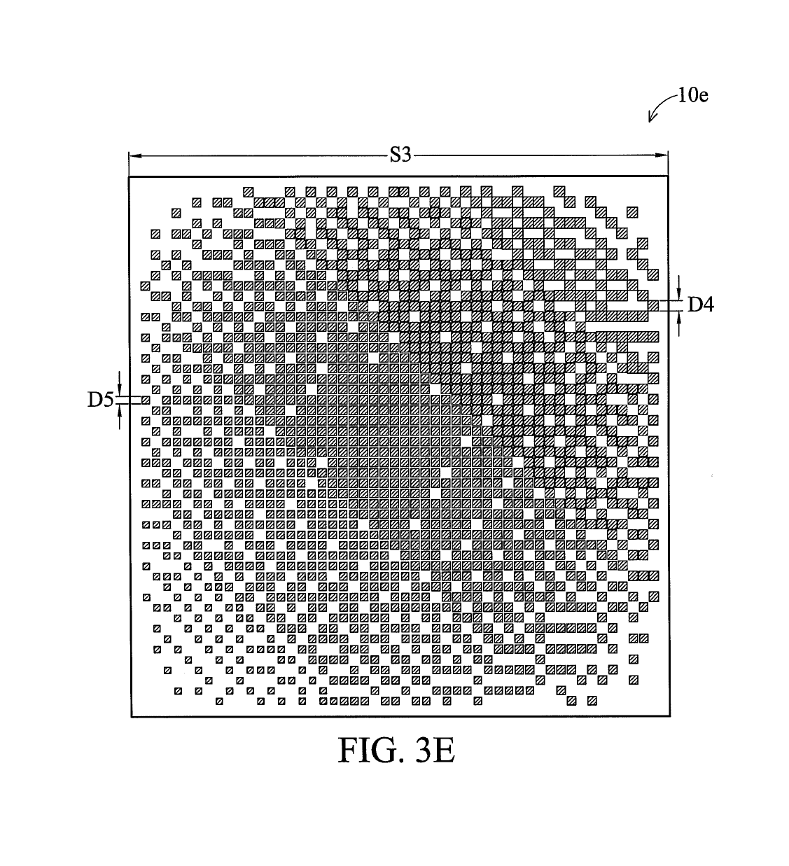

A convex microlens array 106 is disposed on the intervening layer 104 and corresponds to the underlying color filter array (not shown) and the pixel array of the sensing area 102. In the embodiment, the convex microlens array 106 comprises a plurality of convex microlens 106a, in which at least two of the plurality of convex microlenses 106a have different convex heights L. The convex microlenses 106a with different convex heights L are used for compensating the focal depth shift of the plurality of convex microlenses 106a at different chief ray angles (CRA). For example, the convex microlenses 106a in the convex microlens array 106 corresponding to the photosensors 102a near the periphery of the pixel array of the sensing area 102 (hereinafter referred to as the peripheral of the pixel array) have the convex height L lower than that of the convex microlenses 106a corresponding to the photosensors 102a near the center of the pixel array of the sensing area 102 (hereinafter referred to as the central portion of the pixel array). In another embodiment, the convex heights L of the convex microlenses 106a are gradually increased from the peripheral of the pixel array to the central portion of the pixel array, as shown illustratively in FIG. 2B-1. In one embodiment, at least one of the plurality of convex microlenses 106a is asymmetric convex. For example, each convex microlens 106a may have the same convex height L and the convex microlenses 106a corresponding to the peripheral of the pixel array are asymmetric convex and that which are corresponding to the central portion of the pixel array are symmetric convex, as shown illustratively in FIG. 2B-2. Additionally, the convex heights L of the convex microlenses 106a can also be gradually increased from the peripheral of the pixel array to the central portion of the pixel array and the convex microlenses 106a corresponding to the peripheral of the pixel array are asymmetric convex and that which are corresponding to the central portion of the pixel array are symmetric convex, as shown illustratively in FIG. 2B-3.

Referring to 2A to 2B-1, 2B-2, and 2B-3, which are cross sections of various exemplary embodiments of a method for fabricating an image sensor device. As shown in FIG. 2A, a substrate 100 having a sensing area 102 comprising a pixel array therein is provided. The substrate 100, such as a silicon substrate or other semiconductor substrates, may contain a variety of elements, including, for example, transistors, resistors, and other semiconductor elements well known in the art. In order to simplify the diagram, the variety of elements is not depicted. Moreover, isolation regions (not shown) may be formed in the substrate 100 to define active regions for arrangement of the pixel array in the sensing area 102. Each active region (i.e. unit pixel) includes a corresponding photosensor 102a. The photosensors 102a may comprise photodiodes, phototransistors or other photosensors well known in the art.

An intervening layer 104 is formed on the substrate 100. In the embodiment, the transparent layer comprises an ILD layer, an IMD layer, a color filter array, and an overlying passivation or planarization layer. The ILD and IMD layer may be formed by chemical vapor deposition (CVD), plasma enhanced chemical vapor deposition (PECVD), or other deposition processes well known in the art. The ILD and IMD layers may comprise silicon oxide or low k material, such as fluorinated silicate glass (FSG), carbon doped oxide, methyl silsesquioxane (MSQ), hydrogen silsesquioxane (HSQ), or fluorine tetra-ethyl-orthosilicate (FTEOS). Moreover, the color filter array may have red, green and blue color filters formed by, for example, photolithography, such that each color filter can correspond to each unit pixel or photosensor 102a. The passivation or planarization layer may comprise silicon nitride (e.g., SiN, Si₃N₄), silicon oxynitride (e.g., SiON), silicon carbide (e.g., SiC), silicon oxycarbide (e.g., SiOC), or combinations thereof. In order to simply the diagram, only a flat layer 104 is depicted.

Next, a microlens material layer, such as a photoresist layer 105, is coated on the intervening layer 104. Thereafter, lithography is performed on the photoresist layer 105 to form a convex microlens array 106 corresponding to the pixel array of the sensing area 102, as shown in FIG. 2B-1, 2B-2, or 2B-3.

During the formation of the convex microlens array 106, an exposure process 20 is performed on at least two regions of the photoresist layer 105 by at least two binary half-tone masks with different optical transparency distributions, respectively. Note that the term of “optical transparency distribution” means a binary half-tone mask comprising at least two regions having different optical transparencies. In the embodiment, the region of the photoresist layer 105 corresponding to the peripheral of the pixel array is exposed by a first binary half-tone mask 11b and the region of the photoresist layer 105 corresponding to the central portion of the pixel array is exposed by a second binary half-tone mask 11a having an optical transparency distribution different from that of the first binary half-tone mask 11b, as shown in FIG. 2A. The binary half-tone masks 11a and 11b may shift along various directions during exposure. Moreover, the mask projecting patterns on the first and second binary half-tone masks 11b and 11a, respectively, are formed by dispersedly arranging a plurality of opaque dot patterned layers thereon.

FIGS. 3A to 3E are various plan views of the mask projecting patterns 10a, 10b, 10c, 10d, and 10e for the first or second binary half-tone mask 11b or 11a. The mask projecting pattern 10a is substantially the same as the mask projecting pattern 10b. That is, the mask projecting pattern 10a, and 10b have substantially the same arrangement of the opaque dot patterned layers. In particular, the mask projecting patterns 10a and 10b have different pattern sizes S1 and S2 and different dot pattern sizes D1 and D2. For example, the pattern size S1 is larger than the pattern size S2 and the dot pattern size D1 are larger than dot pattern size D2, as shown in FIGS. 3A and 3B.

The mask projecting pattern 10c is also substantially the same as the mask projecting patterns 10a. In particular, the mask projecting patterns 10a and 10c have substantially the same pattern size S1. Moreover, at least two dot patterns in the mask projecting patterns 10c have different dot pattern sizes D1 and D3. For example, the dot pattern size D1 are larger than dot pattern size D3, as shown in FIGS. 3A and 3C.

The mask projecting pattern 10d are different from the mask projecting patterns 10a. In particular, the mask projecting patterns 10a and 10d have substantially the same pattern size S1 and substantially the same dot pattern size D1, as shown in FIGS. 3A and 3D.

The mask projecting pattern 10e is also substantially the same as the mask projecting patterns 10a. In particular, the mask projecting patterns 10a and 10e have the different pattern sizes S1 and S3. Moreover, at least two dot patterns in the mask projecting patterns 10e have different dot pattern sizes D4 and D5. Both of the dot pattern sizes D4 and D5 may different from the dot pattern size D1 or one of the dot pattern sizes D4 and D5 is different from the dot pattern size D1. For example, the dot pattern size D4 is larger than the dot pattern sizes D1 and D5, as shown in FIGS. 3A and 3E.

In one embodiment, such mask projecting patterns 10a and 10b can be used for the first and second binary half-tone masks 11b and 11a respectively, during the exposure process 20. In another embodiment, the mask projecting patterns 10a and 10b can be provided by magnifying or shrinking the image size of mask pattern on a single binary half-tone mask during the exposure process 20. That is, the first and second binary half-tone masks 11ba and 11a are the same mask. A development process 30 is subsequently performed on the exposed photoresist layer 105 to form the convex microlens array 106 comprising a plurality of convex microlens 106a, in which at least two symmetric convex microlenses 106a have different convex heights L. For example, the region of the photoresist layer 105 corresponding to the peripheral of the pixel array is exposed by the mask projecting pattern 10a and the region of the photoresist layer 105 corresponding to the central portion of the pixel array is exposed by the mask projecting pattern 10b, such that the convex heights L of the convex microlenses 106a corresponding to the peripheral of the pixel array are lower than that which are corresponding to the central portion of the pixel array. In particular, the convex heights L of the convex microlenses 106a, which gradually increase from the peripheral of the pixel array to the central portion of the pixel array, can be accomplished by magnifying or shrinking the image size of a mask pattern on a binary half-tone mask at different regions of the photoresist layer 105 during the exposure process 20, as shown in FIG. 2B-1.

In another embodiment, at least two regions of the photoresist layer 105 are exposed by the mask projecting patterns 10a and 10c, respectively, provided by different masks, such as the first and second binary half-tone masks 11b and 11a. A development process 30 is subsequently performed on the exposed photoresist layer 105 to form the convex microlens array 106 comprising a plurality of convex microlens 106a with the same convex heights L. In the embodiment, the region of the photoresist layer 105 corresponding to the peripheral of the pixel array is exposed by the mask projecting pattern 10c and the region of the photoresist layer 105 corresponding to the central portion of the pixel array is exposed by the mask projecting pattern 10a, such that the convex microlenses 106a corresponding to the peripheral of the pixel array are asymmetric convex and that which are corresponding to the central portion of the pixel array are symmetric convex, as shown in FIG. 2B-2.

In yet another embodiment, at least two regions of the photoresist layer 105 are exposed by the mask projecting patterns 10a and 10d, respectively, provided by different masks, such as the first and second binary half-tone masks 11b and 11a. A development process 30 is subsequently performed on the exposed photoresist layer 105 to form the convex microlens array 106 comprising a plurality of symmetric convex microlens 106a with different convex heights L. In the embodiment, the convex microlens array 106 is similar as that shown in FIG. 2B-1.

In further yet another embodiment, at least two regions of the photoresist layer 105 are exposed by the mask projecting patterns 10e and 10a, respectively, provided by different masks, such as the first and second binary half-tone masks 11b and 11a. A development process 30 is subsequently performed on the exposed photoresist layer 105 to form the convex microlens array 106 comprising a plurality of convex microlens 106a with different convex heights L. In the embodiment, the region of the photoresist layer 105 corresponding to the peripheral of the pixel array is exposed by the mask projecting pattern 10e and the region of the photoresist layer 105 corresponding to the central portion of the pixel array is exposed by the mask projecting pattern 10a, such that the convex microlenses 106a corresponding to the peripheral of the pixel array are asymmetric convex and that which are corresponding to the central portion of the pixel array are symmetric convex. Moreover, the convex heights L of the convex microlenses 106a, which gradually increase from the peripheral of the pixel array to the central portion of the pixel array, as shown in FIG. 2B-3.

Typically, the CRA at the peripheral microlenses (i.e. at the region corresponding to the peripheral of the pixel array) is larger than that at the central microlenses (i.e. at the region corresponding to the central portion of the pixel array). The inventors discovered that the focal depth at the peripheral of the microlenses is shallower than that at the central portion of the microlenses when each microlens has the same shape. Consequently, photosensitivity of the image sensor device is reduced because the light passing through the peripheral microlenses cannot be properly focused toward the corresponding photosensors.

According to the mentioned embodiments, however, since the convex microlens array 106 comprises microlenses 106a with different shapes, the focal depth of the light at the peripheral microlenses can be extended so as to be properly focused toward the corresponding photosensors 102a in the pixel array of the sensing area 102. Accordingly, the incident light at different CRA can be properly focused toward the corresponding photosensors, thereby increasing photosensitivity of the image sensor device. Moreover, since the microlenses can be formed by lithography without a conventional reflowing process, the ability to control the microlens profile is increased and manufacturing costs can be reduced.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating an image sensor device, comprising:
providing a substrate having a sensing area comprising a pixel array therein;
coating a photoresist layer over the substrate; and
performing exposure on at least two regions of the photoresist layer by at least two binary half-tone masks, respectively, wherein a first and second binary half-tone masks of the two binary half-tone masks have different optical transparency distributions; and
performing development on the exposed photoresist layer to form a convex microlens array corresponding to the pixel array of the sensing area and comprising at least two microlenses with different convex profiles.

2. The method of claim 1, wherein the first and second binary half-tone masks have the same projecting pattern formed by dispersedly arranging a plurality of opaque dot patterned layers thereon.

3. The method of claim 2, wherein the first and second binary half-tone masks have different projecting pattern sizes and different dot pattern sizes.

4. The method of claim 3, wherein at least two opaque dot patterned layers on the first binary half-tone mask have different dot pattern sizes.

5. The method of claim 2, wherein the first and second binary half-tone masks have the same projecting pattern size and at least two opaque dot patterned layers on the first binary half-tone mask have different dot pattern sizes.

6. The method of claim 1, wherein the first and second binary half-tone masks have different projecting patterns formed by dispersedly arranging a plurality of opaque dot patterned layers thereon, respectively, and the first and second binary half-tone masks have the same projecting pattern size and the same dot pattern sizes.

7. The method of claim 1, wherein the region of the photoresist layer exposed by the first binary half-tone mask corresponds to the peripheral of the pixel array of the sensing area, and the region of the photoresist layer exposed by the second binary half-tone mask corresponds to the central portion of the pixel array of the sensing area.

8. The method of claim 7, wherein the first and second binary half-tone masks have the same projecting pattern formed by dispersedly arranging a plurality of opaque dot patterned layers thereon.

9. The method of claim 8, wherein the first binary half-tone mask have a projecting pattern size and a dot pattern size larger than that of the second binary half-tone mask.

10. The method of claim 9, wherein at least two opaque dot patterned layers on the first binary half-tone mask have different dot pattern sizes.

11. The method of claim 8, wherein the first and second binary half-tone masks have the same projecting pattern size and at least two opaque dot patterned layers on the first binary half-tone mask have different dot pattern sizes.
